(19) United States
(12) Patent Application Publication
(10) Pub. No.: US 2010/0003532 A1
(43) Pub. Date: Jan. 7, 2010

(54) BETA-DIKETIMINATE PRECURSORS FOR METAL CONTAINING FILM DEPOSITION

(76) Inventors: Benjamin J. FEIST, Wilmington, DE (US); Christian Dussarrat, Wilmington, DE (US); Vincent M. Omarjee, Bear, DE (US); Clement Lansalot-Matras, Ibaraki, DE (US)

Correspondence Address: AIR LIQUIDE;Intellectual Property, 2700 POST OAK BOULEVARD, SUITE 1800, HOUSTON, TX, 77056, US

(21) Appl. No.: 12/480,472

(22) Filed: Jun. 8, 2009

Related U.S. Application Data
(60) Provisional application No. 61/059,550, filed on Jun. 6, 2008.

(51) Int. Cl. C23C 16/18; B32B 15/04; C07F 7/28; C07F 7/00

(52) U.S. Cl. 428/457; 427/248.1; 427/255.28; 534/15; 556/32

(57) ABSTRACT

Methods and compositions for depositing a metal containing film on a substrate are disclosed. A reactor, and at least one substrate disposed in the reactor, are provided. A metal containing precursor with at least one β-diketiminate ligand is provided and introduced into the reactor, which is maintained at a temperature of at least 100° C. Metal is deposited onto the substrate through a deposition process to form a thin film on the substrate.

### CROSS-REFERENCE TO RELATED APPLICATIONS

The present application claims the benefit of U.S. Provisional Application Ser. No. 61/059,550, filed Jun. 6, 2008, herein incorporated by reference in its entirety for all purposes.

### BACKGROUND

1. Field of the Invention

This invention relates generally to compositions, methods and apparatus used for use in the manufacture of semiconductor, photovoltaic, LCF-TFT, or flat panel type devices. More specifically, the invention relates to methods and compositions for depositing a metal containing film.

2. Background of the Invention

One of the serious challenges the industry faces is developing new gate dielectric materials for DRAM and capacitors. For decades, silicon dioxide (SiO₂) was a reliable dielectric, but as transistors have continued to shrink and the technology moved from “Full Si” transistor to “Metal Gate/High-k” transistors, the reliability of the SiO₂-based gate dielectric is reaching its physical limits. The need for new high dielectric constant material and processes is increasing and it becomes more and more critical as the size for current technology is shrinking. Dielectric materials containing alkaline earth metals, such as SrTiO₃, or other transition metals can provide a significant advantage in capacitance compared to conventional dielectric materials.

However, metal deposition, can be difficult and chemical and physical properties become more and more important. For instance, atomic layer deposition (“ALD”) has been identified as an important thin film growth technique for microelectronics manufacturing, relying on sequential and saturating surface reactions of alternatively applied precursors, separated by inert gas purging. The surface-controlled nature of ALD enables the growth of thin films of high conformality and uniformity with an accurate thickness control. The need for developing new ALD processes for the high-k materials is clear; unfortunately the successful integration of alkaline earth metals and other transition metals into vapor deposition processes has proven to be difficult.

Although atomic layer deposition of some metal diketonates has been disclosed, those metal diketonates have low volatility, which typically requires the use of organic solvent for use in a liquid injection system, hi addition to low volatility, the metal diketonates generally have poor reactivity, often requiring high substrate temperatures and strong oxidizers to grow a film, which is often contaminated with carbon. Other alkaline earth metal sources, such as those including substituted or unsubstituted cyclopentadienyl ligands, typically have poor volatility as well as low thermal stability, leading to undesirable pyrolysis on the substrate surface.

In addition to ALD, new CVD processes are also required for high-k materials. Here also, the successful integration of alkaline earth metals into vapor deposition processes has proven to be difficult. Consequently there exists a need for new metal containing precursors.

### BRIEF SUMMARY

The invention provides novel methods and compositions for the deposition of metal containing films on a substrate. In an embodiment, a method for depositing a metal containing film on a substrate comprises providing a reactor, and a least one substrate disposed in the reactor. A first precursor is provided, where the first precursor has the general formula:

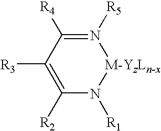

and wherein M is a metal selected from among: alkaline earth metals; scandium; yttrium; lanthanides; titanium; zirconium; hafnium; and combinations thereof; each L is independently an anionic ligand; each Y is independently a neutral ligand; R₂, R₃, and R₄ are independently selected from hydrogen and methyl; R₁ and R₅ are independently selected from methyl, ethyl, isopropyl; tert-butyl and combinations thereof; n is the valance state of M; 0≦z≦5; and 1≦x≦n. The first precursor is introduced into the reactor. The reactor is maintained at a temperature of at least 100° C. and at least part of the precursor is deposited onto the substrate to form a metal containing film.

In an embodiment, a composition is provided, where a metal containing precursor has the general formula:

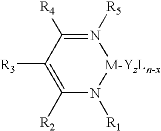

and wherein M is a metal selected from among: alkaline earth metals; scandium; yttrium; lanthanides; titanium; zirconium; hafnium; and combinations thereof; each L is independently an anionic ligand; each Y is independently a neutral ligand; R₂, R₃, and R₄ are independently selected from hydrogen and methyl; R₁ and R₅ are independently selected from methyl, ethyl, isopropyl; tert-butyl and combinations thereof; n is the valance state of M; 0≦z≦5; and 1≦x≦n.

Other embodiments of the current invention may include, without limitation, one or more of the following features:
L is at least one member selected from the group consisting of: a halide; an alkoxide group; an amide group; a mercaptide group; cyanide; an alkyl group; an amidinate group; a cylcopentadienyl; a guanidinate group; an isoureate group; a β-diketiminate group; a β-diketoiminate group; and combinations thereof;
at least one L is a β-diketiminate group with a structure that is the same as the β-diketiminate ligand in formula (I);
at least one L is a β-diketiminate group with a structure that is different than the β-diketiminate ligand in formula (I);
M is calcium, strontium or barium;
M is titanium or zirconium;
Y is at least one member selected from the group consisting of: a carbonyl; a nitrosyl; ammonia; an amine; nitrogen; a phosphine; an alcohol; water; tetrahydrofuran (THF); and combinations thereof;
a second metal containing precursor is introduced into the reactor, where the second metal containing precursor is different from the first metal containing precursor;
at least part of the second metal containing precursor is contacted with the substrate to form a metal containing film;
the metal in the second metal containing precursor is at least one member selected from the group consisting of: titanium; tantalum; bismuth; hafnium; zirconium; lead; niobium; magnesium; aluminum; and combinations thereof;
the reactor is maintained at a temperature between about 100° C. to about 500° C., preferably at a temperature between about 150° C. and about 350° C.
the reactor is maintained at a pressure between about 1 Pa and about 10⁵ Pa, preferably at a pressure between about 25 Pa and about 10³ Pa;

introducing at least one reducing gas into the reactor, wherein the reducing gas is selected from H₂; NH₃; SiH₄; Si₂H₆; Si₃H₈; SiH₂Me₂, SiH₂Et₂, N(SiH₃)₃, hydrogen radicals; and mixtures thereof;

the first metal containing precursor and the reducing gas are introduced into the chamber either substantially simultaneously, or sequentially;
the first metal containing precursor and the reducing gas are introduced into the chamber substantially simultaneously, and the chamber is configured for chemical vapor deposition;
the first metal containing precursor and the reducing gas are introduced into the chamber sequentially, and the chamber is configured for atomic layer deposition.
introducing at least one oxidizing gas into the reactor, wherein the oxidizing gas is selected from: O₂; O₃; H₂O; NO; oxygen radicals; and mixtures thereof;
the first metal containing precursor and the oxidizing gas are introduced into the chamber either substantially simultaneously, or sequentially;
the first metal containing precursor and the oxidizing gas are introduced into the chamber substantially simultaneously, and the chamber is configured for chemical vapor deposition;
the first metal containing precursor and the oxidizing gas are introduced into the chamber sequentially, and the chamber is configured for atomic layer deposition;
the first metal containing precursor is one of: tri-(4-N-ethylamino-3-penten-2-N-ethyliminato)titanium; (4-N-ethylamino-3-penten-2-N-ethyliminato)-tri(dimethylamino)zirconium; di-(4-N-tertbutylamino-3-penten-2-N-tertbutyliminato)strontium; di-(4-N-tertbutylamino-3-penten-2-N-tertbutyliminato)calcium; di-(4-N-tertbutylamino-3-penten-2-N-tertbutyliminato)barium; di-(4-N-isopropylamino-3-penten-2-N-isopropyliminato)strontium; and di-(4-N-isopropylamino-3-penten-2-N-isopropyliminato)calcium.

The foregoing has outlined rather broadly the features and technical advantages of the present invention in order that the detailed description of the invention that follows may be better understood. Additional features and advantages of the invention will be described hereinafter that form the subject of the claims of the invention. It should be appreciated by those skilled in the art that the conception and the specific embodiments disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### Notation and Nomenclature

Certain terms are used throughout the following description and claims to refer to various components and constituents. This document does not intend to distinguish between components that differ in name but not function.

As used herein, the term “alkyl group” refers to saturated functional groups containing exclusively carbon and hydrogen atoms. Further, the term “alkyl group” may refer to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the abbreviation, “Me,” refers to a methyl group; the abbreviation, “Et,” refers to an ethyl group; the abbreviation, “tBu,” refers to a tertiary butyl group; and the abbreviation, “iPr” refers to an isopropyl group.

As used herein, the term “independently” when used in the context of describing R groups should be understood to denote that the subject R group is not only independently selected relative to other R groups bearing different subscripts or superscripts, but is also independently selected relative to any additional species of that same R group. For example in the formula MR¹ₓ (NR²R³)₍₄₋ₓ₎, where x is 2 or 3, the two or three R¹ groups may, but need not be identical to each other or to R² or to R³. Further, it should be understood that unless specifically stated otherwise, values of R groups are independent of each other when used in different formulas.

### DESCRIPTION OF PREFERRED EMBODIMENTS

Generally, embodiments of the invention relate to a metal containing precursor, and methods for depositing a metal containing film with the precursor.

In these embodiments, the metal containing precursor has the general formula:

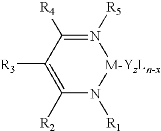

and wherein M is a metal selected from among: alkaline earth metals; scandium; yttrium; lanthanides; titanium; zirconium; hafnium; and combinations thereof; each L is independently an anionic ligand; each Y is independently a neutral ligand; R₂, R₃, and R₄ are independently selected from hydrogen and methyl; R₁ and R₅ are independently selected from methyl, ethyl, isopropyl; tert-butyl and combinations thereof; n is the valance state of M; 0≦z≦5; and 1≦x≦n.

In some embodiments, L may be selected from a halide; an alkoxide group; an amide group; a mercaptide group; cyanide; an alkyl group; an amidinate group; a cylcopentadienyl; a guanidinate group; an isoureate group; a β-diketiminate group; a β-diketoiminate group; and combinations of these. In some embodiments, at least one L is a μ-diketiminate, which may be the same or different from the β-diketiminate ligand in formula (I). In some embodiments, Y may be selected from a carbonyl; a nitrosyl; ammonia; an amine; nitrogen; a phosphine; an alcohol; water; tetrahydrofuran (THF); and combinations of these.

In some embodiments, the first metal precursor may be one of the following precursors, which are shown structurally below also:
(II) tri-(4-N-ethylamino-3-penten-2-N-ethyliminato)titanium;
(III) (4-N-ethylamino-3-penten-2-N-ethyliminato)-tri(dimethylamino)zirconium;
(IV) di-(4-N-tertbutylamino-3-penten-2-N-tertbutyliminato)strontium;
(V) di-(4-N-tertbutylamino-3-penten-2-N-tertbutyliminato)calcium;
(VI) di-(4-N-tertbutylamino-3-penten-2-N-tertbutyliminato)barium;
(VII) di-(4-N-isopropylamino-3-penten-2-N-isopropyliminato)strontium; and
(VIII) di-(4-N-isopropylamino-3-penten-2-N-isopropyliminato)calcium.

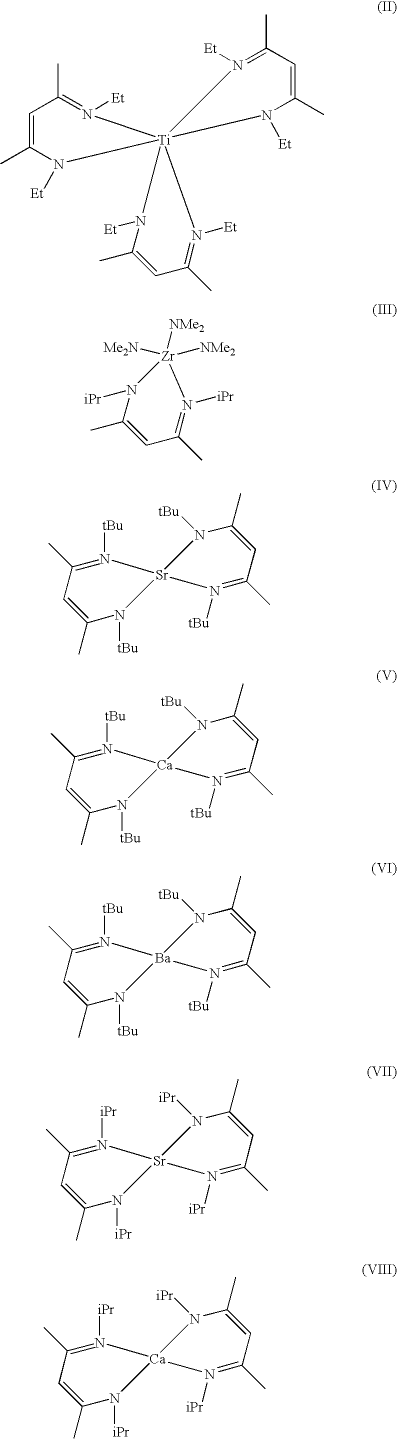

The disclosed precursors may be deposited to form a thin film using any deposition methods known to those of skill in the art. Examples of suitable deposition methods include without limitation, conventional CVD, low pressure chemical vapor deposition (LPCVD), plasma enhanced chemical vapor depositions (PECVD), atomic layer deposition (ALD), pulsed chemical vapor deposition (P-CVD), plasma enhanced atomic layer deposition (PE-ALD), or combinations thereof.

In an embodiment, the first precursor is introduced into a reactor in vapor form. The precursor in vapor form may be produced by vaporizing a liquid precursor solution, through a conventional vaporization step such as direct vaporization, distillation, or by bubbling an inert gas (e.g. N₂, He, Ar, etc.) into the precursor solution and providing the inert gas plus precursor mixture as a precursor vapor solution to the reactor. Bubbling with an inert gas may also remove any dissolved oxygen present in the precursor solution.

The reactor may be any enclosure or chamber within a device in which deposition methods take place such as without limitation, a cold-wall type reactor, a hot-wall type reactor, a single-wafer reactor, a multi-wafer reactor, or other types of deposition systems under conditions suitable to cause the precursors to react and form the layers.

Generally, the reactor contains one or more substrates on to which the thin films will be deposited. The one or more substrates may be any suitable substrate used in semiconductor, photovoltaic, flat panel or LCD-TFT device manufacturing. Examples of suitable substrates include without limitation, silicon substrates, silica substrates, silicon nitride substrates, silicon oxy nitride substrates, tungsten substrates, or combinations thereof. Additionally, substrates comprising tungsten or noble metals (e.g. platinum, palladium, rhodium or gold) may be used. The substrate may also have one or more layers of differing materials already deposited upon it from a previous manufacturing step.

In some embodiments, in addition to the first precursor, a reactant gas may also be introduced into the reactor. In some of these embodiments, the reactant gas may be an oxidizing gas such as one of oxygen, ozone, water, hydrogen peroxide, nitric oxide, nitrogen dioxide, radical species of these, as well as mixtures of any two or more of these. In some other of these embodiments, the reactant gas may be a reducing gas such as one of hydrogen, ammonia, a silane (e.g. SiH₄; Si₂H₆; Si₃H₈), SiH₂Me₂; SiH₂Et₂; N(SiH₃)₃; radical species of these, as well as mixtures of any two or more of these.

In some embodiments, and depending on what type of film is desired to be deposited, a second precursor may be introduced into the reactor. The second precursor comprises another metal source, such as copper, praseodymium, manganese, ruthenium, titanium, tantalum, bismuth, zirconium, hafnium, lead, niobium, magnesium, aluminum, lanthanum, or mixtures of these. In embodiments where a second metal containing precursor is utilized, the resultant film deposited on the substrate may contain at least two different metal types.

The first precursor and any optional reactants or precursors may be introduced sequentially (as in ALD) or simultaneously (as in CVD) into the reaction chamber. In some embodiments, the reaction chamber is purged with an inert gas between the introduction of the precursor and the introduction of the reactant. In one embodiment, the reactant and the precursor may be mixed together to form a reactant/precursor mixture, and then introduced to the reactor in mixture form. In some embodiments, the reactant may be treated by a plasma, in order to decompose the reactant into its radical form. In some of these embodiments, the plasma may generally be at a location removed from the reaction chamber, for instance, in a remotely located plasma system. In other embodiments, the plasma may be generated or present within the reactor itself. One of skill in the art would generally recognize methods and apparatus suitable for such plasma treatment.

In some embodiments, the temperature and the pressure within the reactor are held at conditions suitable for ALD or CVD depositions. For instance, the pressure in the reactor may be held between about 1 Pa and about 10⁵ Pa, or preferably between about 25 Pa and 10³ Pa, as required per the deposition parameters. Likewise, the temperature in the reactor may be held between about 100° C. and about 500° C., preferably between about 150° C. and about 350° C.

In some embodiments, the precursor vapor solution and the reaction gas, may be pulsed sequentially or simultaneously (e.g. pulsed CVD) into the reactor. Each pulse of precursor may last for a time period ranging from about 0.01 seconds to about 10 seconds, alternatively from about 0.3 seconds to about 3 seconds, alternatively from about 0.5 seconds to about 2 seconds. In another embodiment, the reaction gas may also be pulsed into the reactor. In such embodiments, the pulse of each gas may last for a time period ranging from about 0.01 seconds to about 10 seconds, alternatively from about 0.3 seconds to about 3 seconds, alternatively from about 0.5 seconds to about 2 seconds.

While embodiments of this invention have been shown and described, modifications thereof can be made by one skilled in the art without departing from the spirit or teaching of this invention. The embodiments described herein are exemplary only and not limiting. Many variations and modifications of the composition and method are possible and within the scope of the invention. Accordingly the scope of protection is not limited to the embodiments described herein, but is only limited by the claims which follow, the scope of which shall include all equivalents of the subject matter of the claims.

What is claimed is:

1. A method of forming a metal containing film on a substrate, comprising:
a) providing a reactor and at least one substrate disposed therein;
b) introducing a first metal containing precursor into the reactor, wherein the first metal containing precursor has the general formula (I): 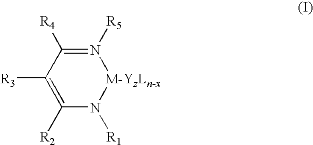
wherein:
M is a metal selected from the group consisting of: alkaline earth metals; scandium; yttrium; a lanthanide; titanium; zirconium; hafnium; and combinations thereof:
each L is independently an anionic ligand;
each Y is independently a neutral ligand;
R2, R3, and R4 are independently selected from hydrogen and methyl;
R1 and R5 are independently selected from methyl, ethyl, isopropyl, tert-butyl and combinations thereof
n is the valance state of M;
0≦z≦5; and
1≦x≦n;
C) maintaining the reactor at a temperature of at least about 100° C.; and
d) contacting the first metal containing precursor with the substrate to form a metal containing film.

2. The method of claim 1, wherein L is at least one member selected from the group consisting of: a halide; an alkoxide group; an amide group; a mercaptide group; cyanide; an alkyl group; an amidinate group; a cylcopentadienyl; a guanidinate group; an isoureate group; a β-diketiminate group; a β-diketoiminate group; and combinations thereof.

3. The method of claim 1, wherein at least one L is a β-diketiminate group with a structure that is the same as the β-diketiminate ligand in formula (I).

4. The method of claim 1, wherein at least one L is a β-diketiminate group with a structure that is different than the β-diketiminate ligand in formula (I).

5. The method of claim 1, wherein M is calcium, strontium or barium.

6. The method of claim 1, wherein Y is at least one member selected from the group consisting of: a carbonyl; a nitrosyl; ammonia; an amine; nitrogen; a phosphine; an alcohol; water; tetrahydrofuran (THF); and combinations thereof.

7. The method of claim 1, further comprising:
a) introducing a second metal containing precursor into the reactor, wherein the second metal containing precursor is different from the first precursor; and
b) contacting the second metal containing precursor with the substrate to form a metal containing film.

8. The method of claim 7, wherein the metal in the second metal containing precursor is at least one member selected from the group consisting of: titanium; tantalum; bismuth; hafnium; zirconium; lead; niobium; magnesium; aluminum; and combinations thereof.

9. The method of claim 1, further comprising maintaining the reactor at a temperature between about 100° C. to about 500° C.

10. The method of claim 9, further comprising maintaining the reactor at a temperature between about 150° C. and about 350° C.

11. The method of claim 1, further comprising maintaining the reactor at a pressure between about 1 Pa and about 10⁵ Pa.

12. The method of claim 11, further comprising maintaining the reactor at a pressure between about 25 Pa and about 10³ Pa.

13. The method of claim 1, further comprising introducing at least one reducing gas into the reactor, wherein the reducing gas comprises at least one member selected from the group consisting of H₂; NH₃; SiH₄; Si₂H₆; Si₃H₈; SiH₂Me₂, SiH₂Et₂, N(SiH₃)₃, hydrogen radicals; and mixtures thereof.

14. The method of claim 13, wherein the first metal containing precursor and the reducing gas are introduced into the chamber either substantially simultaneously, or sequentially.

15. The method of claim 13, wherein the first metal containing precursor and the reducing gas are introduced into the chamber substantially simultaneously, and the chamber is configured for chemical vapor deposition.

16. The method of claim 13, wherein the first metal containing precursor and the reducing gas are introduced into the chamber sequentially, and the chamber is configured for atomic layer deposition.

17. The method of claim 1, further comprising introducing at least one oxidizing gas into the reactor, wherein the oxidizing gas comprises at least one member selected from the group consisting of: O₂; O₃; H₂O; NO; oxygen radicals; and mixtures thereof.

18. The method of claim 17, wherein the first metal containing precursor and the oxidizing gas are introduced into the chamber either substantially simultaneously, or sequentially.

19. The method of claim 17, wherein the first metal containing precursor and the oxidizing gas are introduced into the chamber substantially simultaneously, and the chamber is configured for chemical vapor deposition.

20. The method of claim 17, wherein the first metal containing precursor and the oxidizing gas are introduced into the chamber sequentially, and the chamber is configured for atomic layer deposition.

21. The method of claim 1, wherein the first metal containing precursor comprises at least one member selected from the group consisting of: tri-(4-N-ethylamino-3-penten-2-N-ethyliminato)titanium; (4-di-(4-N-tertbutylamino-3-penten-2-N-tertbutyliminato)strontium; di-(4-N-tertbutylamino-3-penten-2-N-tertbutyliminato)calcium; di-(4-N-tertbutylamino-3-penten-2-N-tertbutyliminato)barium; di-(4-N-isopropylamino-3-penten-2-N-isopropyliminato)strontium; and di-(4-N-isopropylamino-3-penten-2-N-isopropyliminato)calcium.

22. A metal containing thin film coated substrate comprising the product of the method of claim 1.

23. A composition comprising a metal containing precursor of the general formula: 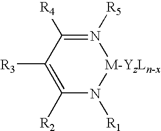
wherein:
M is a metal selected from the group consisting of: alkaline earth metals; scandium; yttrium; a lanthanide; titanium; zirconium;
hafnium; and combinations thereof:
each L is independently an anionic ligand;
each Y is independently a neutral ligand;
R2, R3, and R4 are independently selected from hydrogen and methyl;
R1, R1 and R5 are independently selected from methyl, ethyl, isopropyl, tert-butyl and combinations thereof
n is the valance state of M;
0≦z≦5; and
1≦x≦n.

24. The composition of claim 23, comprising at least one member selected from the group consisting of: tri-(4-N-ethylamino-3-penten-2-N-ethyliminato)titanium; and (4-N-ethylamino-3-penten-2-N-ethyliminato)-tri(dimethylamino)zirconium.
